(19) United States
(12) Patent Application Publication
(10) Pub. No.: US 2024/0176931 A1
(43) Pub. Date: May 30, 2024

(54) APPARATUS AND METHOD FOR REAL-TIME VOLUMETRIC RENDERING OF DYNAMIC PARTICLES

(71) Applicant: Tencent America LLC, Palo Alto, CA (US)

(72) Inventors: Rundong WU; Yu GUO, New York, NY (US); Bo YANG, Los Angeles, CA (US)

(73) Assignee: Tencent America LLC, Palo Alto, CA (US)

(21) Appl. No.: 18/070,326

(22) Filed: Nov. 28, 2022

(51) Int. Cl. G06F 30/23; G06F 30/25; G06T 15/50; G06T 17/20

(52) U.S. Cl. CPC G06F 30/23; G06F 30/25; G06T 15/50; G06T 17/20

(57) ABSTRACT

A method is provided for real-time volumetric rendering of dynamic particles for a processing circuitry. The method includes converting particle data representing each of the dynamic particles into a density volume representing a density distribution of the respective dynamic particle distributed in a 3D space, precomputing a light distribution within the density volume representing a light value for each grid point within the density volume using ray marching from a light source, rendering the dynamic particles in real-time by computing pixel color values determined using ray marching toward a viewpoint position, the density volume, and the light distribution, and outputting a representation of the dynamic particles based on the rendering. The method also includes generating the particle data representing simulated particles composed of a simulated material by a physically-based simulation of natural phenomena, where the generated particle data may include simulated particles movement in the 3D space.

### TECHNICAL FIELD

The present disclosure relates generally to processing systems, including one or more techniques for graphics processing.

### BACKGROUND

Computing devices often utilize a graphics processing unit (GPU) or central processing unit (CPU) to render graphical data for display. Such computing devices may include, for example, computer workstations, mobile phones such as smartphones, embedded systems, personal computers, tablet computers, and video game consoles. GPUs process instructions and/or data in a graphics processing pipeline that includes one or more processing stages that operate together to execute graphics processing commands and output a frame. A CPU may control the operation of the GPU by issuing one or more graphics processing commands to the GPU. Modern day CPUs are typically capable of concurrently executing multiple applications, each of which may need to utilize the GPU during execution. A device that provides content for visual presentation on a display generally includes a GPU.

Typically, a GPU of a device is configured to perform the processes in a graphics processing pipeline. However, with the increasing complexity of rendered content and the physical constraints of GPU memory, there has developed an increased need for improved computer or graphics processing.

### SUMMARY

The following presents a simplified summary of one or more aspects in order to provide a basic understanding of such aspects. This summary is not an extensive overview of all contemplated aspects, and is intended to neither identify key elements of all aspects nor delineate the scope of any or all aspects. Its sole purpose is to present some concepts of one or more aspects in a simplified form as a prelude to the more detailed description that is presented later.

The present disclosure relates to methods and apparatuses for graphics processing. An aspect of the subject matter described in this disclosure is implemented in a method for real-time volumetric rendering of dynamic particles. The method includes converting particle data representing each of the dynamic particles into a density volume representing a density distribution of dynamic particles distributed in a three-dimensional (3D) space. The method also includes precomputing a light distribution within the density volume representing a light value for each grid point within the density volume using ray marching from a light source. The grid points within the density volume correspond to fixed reference positions. The method further includes rendering the dynamic particles in real-time by computing pixel color values determined using (i) ray marching toward a viewpoint position, (ii) the density volume, and (iii) the light distribution. The method includes outputting a representation of the dynamic particles based on the rendering.

Another further aspect of the subject matter described in this disclosure can be implemented in an apparatus for real-time volumetric rendering of dynamic particle. The apparatus includes processing circuitry that is configured to convert particle data representing each of the dynamic particles into a density volume representing a density distribution of dynamic particles distributed in a three-dimensional (3D) space. The processing circuitry is configured to precompute a light distribution within the density volume representing a light value for each grid point within the density volume using ray marching from a light source. The grid points within the density volume correspond to fixed reference positions. The processing circuitry is configured to render the dynamic particles in real-time by computing pixel color values determined using (i) ray marching toward a viewpoint position, (ii) the density volume, and (iii) the light distribution, and cause an output of a representation of the dynamic particles based on the rendering.

Yet another further aspect of the subject matter described in this disclosure can be implemented in a system for real-time volumetric rendering of dynamic particles. The system includes first processing circuitry, second processing circuitry, and control circuitry. The control circuitry is configured to control the first processing circuitry to convert particle data representing each of the dynamic particles of a first frame into a density volume representing a density of dynamic particles distributed in a three-dimensional (3D) space. The control circuitry is also configured to control the first processing circuitry to precompute light distribution within the density volume representing a light value for each grid point within the density volume in the first frame using ray marching toward a light source. Grid points within the density volume correspond to fixed reference positions. The control circuitry is also configured to copy the density volume and the light distribution of the first frame from the first processing circuitry to the second processing circuitry upon completion of the precomputing in the first processing circuitry with respect to the first frame. The control circuitry is further configured to control the first processing circuitry to convert particle data of a second frame into a density volume. The control circuitry is further configured to control the second processing circuitry to render the dynamic particles in the first frame in real-time by computing pixel color values determined using (i) ray marching toward a viewpoint position, (ii) the density volume, and (iii) the light distribution copied from the first processing circuitry. The control circuitry is also configured to cause an output of a representation of the dynamic particles in the first frame based on the rendering.

Another further aspect of the subject matter described in this disclosure can be implemented in a non-transitory computer-readable storage medium storing instructions which when executed by at least one processor cause to processor to perform converting particle data representing each of the dynamic particles into a density volume representing a density distribution of dynamic particles distributed in a three-dimensional (3D) space. The processor is also configured to precompute a light distribution within the density volume representing a light value for each grid point within the density volume using ray marching from a light source. The processor is further configured to render the dynamic particles in real-time by computing pixel color values determined using (i) ray marching toward a viewpoint position, (ii) the density volume, and (iii) the light distribution. The processor is further configured to cause an output of a representation of the dynamic particles based on the rendering.

To the accomplishment of the foregoing and related ends, the one or more aspects include the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF DRAWINGS

Details of one or more aspects of the subject matter described in this disclosure are set forth in the accompanying drawings and the description below. However, the accompanying drawings illustrate only some typical aspects of this disclosure and are therefore not to be considered limiting of its scope. Other features, aspects, and advantages will become apparent from the description, the drawings and the claims.

FIG. 1A is a block diagram that illustrates an example of a content generation system in accordance with one or more techniques of this disclosure.

FIG. 1B is a block diagram that illustrates an example of a content generation system in accordance with one or more techniques of this disclosure.

FIG. 2 illustrates an example diagram for a graphics processing pipeline in accordance with one or more techniques of this disclosure.

FIG. 3A illustrates an example diagram of representing density and lighting distribution as an axis-aligned bounding box in accordance with one or more techniques of this disclosure.

FIG. 3B illustrates an example diagram of representing density and lighting distribution as a froxel volume in accordance with one or more techniques of this disclosure.

FIG. 4 illustrates an example of a slice-by-slice light precomputation in accordance with one or more techniques of this disclosure.

FIG. 5 illustrates a flowchart of an example method for graphics processing in accordance with one or more techniques of this disclosure.

FIG. 6 illustrates a flowchart of an example method for graphics processing utilizing dual processing circuitry in accordance with one or more techniques of this disclosure.

FIG. 7A illustrates an example diagram for a graphics processing pipeline using a single processing circuitry according to one or more techniques of this disclosure.

FIG. 7B illustrates an example diagram for a graphics processing pipeline using dual processing circuitries according to one or more techniques of this disclosure.

Like reference numbers and designations in the various drawings indicate like elements.

### DETAILED DESCRIPTION

The following description is directed to some exemplary aspects for the purposes of describing innovative aspects of this disclosure. However, a person having ordinary skill in the art will readily recognize that the teachings herein can be applied in a multitude of different ways.

Related systems have implemented volumetric rendering methods in off-line applications. In the off-line applications, dense natural material such as snow is usually rendered with a volumetric representation. First, the dense natural material particles are converted to a density volume and then rendered with various path tracing algorithms such as delta tracking and residual tracking. These methods may produce realistic and physically accurate results but require taking many samples to reduce the noise and, thus, consume a substantial amount of computation time. Therefore, these implementations are not suited for real-time applications to render dynamic dense natural material.

Related systems have also implemented snow rendering and volumetric rendering in real-time applications. There are a few ways to render snow in real-time applications such as in video games. For static scenes (e.g., landscape covered by snow), polygon meshes with subsurface scattering materials, which may be rendered quickly, may be utilized. However, this approach cannot deal with dynamic particles due to the difficulty in capturing the complex geometry of the particles using polygons.

Volume rendering has also been used in game engines such as Unreal Engine. These real-time volume rendering techniques include volumetric clouds and volumetric fog (e.g., natural materials that are low-density medium) which can be rendered efficiently with large ray marching steps. In contrast, translucent material such as snow, ash, or dust have a high-density medium which requires smaller ray marching steps that will increase the computational cost. As such, there exists a need for optimizations to be able to render high-density materials using ray marching in real-time applications.

Aspects of the present disclosure can create more a realistic simulation and real-time rendering of natural materials by implementing volumetric rendering of dynamic elements, such as natural translucent (e.g., snow, dust, or ash) materials generated by physically-based simulation. For instance, aspects of the present disclosure provide a GPU pipeline to volumetrically render simulated natural particles with high-density in real-time applications. By doing so, when aspects of present disclosure simulate these natural particles, the data particles are converted into a volume texture and then ray marching is used to compute the interaction between light and medium. As such, aspects of the present disclosure may create more accurate shading, and more physically accurate depictions of high-density natural particles than related rendering techniques. In addition, some aspects of the present disclosure implement several graphics processing optimizations to improve performance by reducing computation cost and increasing frame rate.

Various aspects of systems, apparatuses, computer program products, and methods are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of this disclosure to those skilled in the art. Based on the teachings herein one skilled in the art should appreciate that the scope of this disclosure is intended to cover any aspect of the systems, apparatuses, computer program products, and methods disclosed herein, whether implemented independently of, or combined with, other aspects of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. Any aspect disclosed herein may be embodied by one or more elements of a claim.

Although various aspects are described herein, many variations and permutations of these aspects fall within the scope of this disclosure. Although some potential benefits and advantages of aspects of this disclosure are mentioned, the scope of this disclosure is not intended to be limited to particular benefits, uses, or objectives. Rather, aspects of this disclosure are intended to be broadly applicable to different wireless technologies, system configurations, networks, and transmission protocols, some of which are illustrated by way of example in the figures and in the following description. The detailed description and drawings are merely illustrative of this disclosure rather than limiting, the scope of this disclosure being defined by the appended claims and equivalents thereof.

Several aspects are presented with reference to various apparatus and methods. These apparatus and methods are described in the following detailed description and illustrated in the accompanying drawings by various blocks, components, circuits, processes, algorithms, and the like (collectively referred to as “elements”). These elements may be implemented using electronic hardware, computer software, or any combination thereof. Whether such elements are implemented as hardware or software depends upon the particular application and design constraints imposed on the overall system.

By way of example, an element, or any portion of an element, or any combination of elements may be implemented as a “processing system” that includes one or more processors (which may also be referred to as processing circuitry). One or more processors in the processing system may execute software. Software can be construed broadly to mean instructions, instruction sets, code, code segments, program code, programs, subprograms, software components, applications, software applications, software packages, routines, subroutines, objects, executables, threads of execution, procedures, functions, etc., whether referred to as software, firmware, middleware, microcode, hardware description language, or otherwise. The term application may refer to software. As described herein, one or more techniques may refer to an application, i.e., software, being configured to perform one or more functions. In such examples, the application may be stored on a memory, e.g., on-chip memory of a processor, system memory, or any other memory. Hardware described herein, such as a processor may be configured to execute the application. For example, the application may be described as including code that, when executed by the hardware, causes the hardware to perform one or more techniques described herein. As an example, the hardware may access the code from a memory and execute the code accessed from the memory to perform one or more techniques described herein. In some examples, components are identified in this disclosure. In such examples, the components may be hardware, software, or a combination thereof. The components may be separate components or sub-components of a single component.

Accordingly, in one or more examples described herein, the functions described may be implemented in hardware, software, or any combination thereof. If implemented in software, the functions may be stored on or encoded as one or more instructions or code on a computer-readable medium. Computer-readable media includes computer storage media. Storage media may be any available media that can be accessed by a computer. By way of example, and not limitation, such computer-readable media can comprise a random-access memory (RAM), a read-only memory (ROM), an electrically erasable programmable ROM (EEPROM), optical disk storage, magnetic disk storage, other magnetic storage devices, combinations of the aforementioned types of computer-readable media, or any other medium that can be used to store computer executable code in the form of instructions or data structures that can be accessed by a computer.

This disclosure includes techniques for real-time volumetric rendering of elements, such as high-density materials generated by physically-based simulation. Aspects of this disclosure enable realistic simulations of dynamic high-density natural materials in real-time applications such as video games that include an interaction with natural environments. In addition, the disclosed real-time volumetric rendering techniques improve the rendering of graphical content, and/or reduce the load of a processing unit, i.e., any processing unit configured to perform one or more techniques described herein, such as a GPU (or processing circuitry). Other example benefits are described throughout this disclosure.

As used herein, instances of the term “content” may refer to “graphical content,” “image,” and vice versa. This is true regardless of whether the terms are being used as an adjective, noun, or other parts of speech. In some examples, as used herein, the term “graphical content” may refer to a content produced by one or more processes of a graphics processing pipeline. In some examples, as used herein, the term “graphical content” may refer to a content produced by a processing unit configured to perform graphics processing. In some examples, as used herein, the term “graphical content” may refer to a content produced by a graphics processing unit.

As used herein, the term “display content” may refer to content generated by a processing unit configured to perform displaying processing. In some examples, as used herein, the term “display content” may refer to content generated by a display processing unit. Graphical content may be processed to become display content. For example, a graphics processing unit may output graphical content, such as a frame, to a buffer (which may be referred to as a frame buffer). A display processing unit may read the graphical content, such as one or more frames from the buffer, and perform one or more display processing techniques thereon to generate display content. For example, a display processing unit may be configured to perform composition on one or more rendered layers to generate a frame. As another example, a display processing unit may be configured to compose, blend, or otherwise combine two or more layers together into a single frame. A display processing unit may be configured to perform scaling, e.g., upscaling or downscaling, on a frame. In some examples, a frame may refer to a layer. In other examples, a frame may refer to two or more layers that have already been blended together to form the frame, i.e., the frame includes two or more layers, and the frame that includes two or more layers may subsequently be blended.

In general, GPUs (or processing circuitries) can be used to render three-dimensional (3D) scenes. Because such rendering of 3D scenes can be memory bandwidth-intensive, a specialized graphics memory (“GMEM”) may be used. GMEM may be located close to the graphics-processing core of the GPU so that it has a high memory bandwidth (i.e., read and write access to the GMEM is fast). A scene can be rendered by the graphics processing core of the GPU to the GMEM, and the scene can be resolved from GMEM to memory (e.g., a frame buffer) so that the scene can then be displayed at a display device. The rendering of an entire frame may be referred to as immediate mode rendering. However, the size of the GMEM is limited due to physical memory constraints, such that the GMEM may not have sufficient memory capacity to contain an entire three-dimensional scene (e.g., an entire frame).

Realistically simulating and rendering dense natural translucent materials (e.g., snow, ash, or dust) is difficult for real-time applications such as video games that include interaction with natural environments or any other real-time applications that involve a natural environment such as VR tourism or cultural heritage digitization due to the high-density of the natural materials. Accurate physically-based algorithms are essential to realistic results, but have been too prohibitively computationally expensive to be applied in real-time applications. However, with the rapid development of GPU computing power, it has only recently become feasible to physically simulate and render these effects in real-time.

In the past few decades, path tracing and its variants have become the standard method for off-line rendering. Path tracing includes a computer graphics algorithm for rendering 3D scenes which faithfully produce global illumination. The algorithm stochastically samples many paths of light transport and then computes and accumulates a contribution of all paths to obtain the result to be rendered on screen pixels. Specifically, path tracing samples the paths of light in a 3D scene. After light is emitted from the light source, a light ray travels in a straight line until it scatters on the surface of an object or in the medium, which makes the light change direction and continue in the new direction until it hits another scattering point. The path tracing algorithm simulates such behavior of light and generates a plurality of light paths in the 3D scene to estimate the overall lighting in the scene.

Path tracing can be used for rendering volumetric materials such as snow because, unlike surface rendering where light continues traveling in a straight line until it hits a surface, in volumetric rendering, the light may scatter anywhere inside the medium volume. To simulate this, path tracing randomly generates a scatter-free path length as the light travels in the medium and lets the light scatter at the end of the scatter-free length. There are also various ways to sample the scatter free path length such as delta tracking and ratio tracking.

Path tracing may need an enormous number of light path samples to evaluate the light values to be shown on each pixel. As such, the rendering result will be noisy if the number of samples is small. Thus, in order to get a noise-free result, hundreds of samples are needed for each pixel. However, this means that rendering a clean frame via path tracing may take minutes or even hours depending on the complexity of the scene, which is prohibitively expensive for real-time applications.

Mesh with subsurface scattering material may be used to render static snow scenes. The mesh uses a collection of small triangles to represent the surface of the snow. Subsurface scattering is a modeling technique used to render translucent materials. For instance, subsurface scattering involves modeling light penetrating the material, scattering beneath, and then bouncing back out of the surface. For real-time rendering, a GPU has a rasterization pipeline that may render triangles quickly, which is different from path tracing in off-line rendering. Accordingly, the triangle mesh may be suitable for representing the surface of translucent material, but cannot efficiently capture the complicated geometry of translucent materials represented by dynamic particles (e.g., falling snow particles) since this would require a large number of triangles which is prohibitively computationally expensive.

Sprites may also be used to render dynamic translucent particles. This approach is simple, but cannot produce realistic results. Sprite may refer to a 2D bitmap that is drawn on the screen. When rendering the translucent particles, a sprite bit map, which is facing the camera, is placed and drawn at each particle's location. This approach is suitable for rendering moving particles, but the 2D bitmap cannot reproduce lighting and shadowing effects present in translucent particles well and results in an unrealistic repetitive pattern.

As described herein, exemplary implementations use volumetric rendering to render dynamic snow particles. Volumetric rendering includes a method of rendering light that interacts with a medium within a volume that may scatter and become absorbed by the material before reaching the camera.

Volumetric rendering techniques may be used to render materials other than snow. The most common are volumetric clouds and volumetric fog. For instance, volumetric clouds and/or fog may be rendered using ray marching techniques. Ray marching is a method of performing volumetric rendering. The ray marching technique simulates a ray which goes through a volume of medium. Samples are taken at fixed intervals along the ray to calculate the interaction between the light and the medium and the calculations are accumulated along the ray to obtain the result. However, the ray marching techniques have only been applied to low-density mediums such as clouds and fogs in game engines because the low-density mediums are visually fuzzier than high-density materials. This means that the density variation of the mediums is smaller so that larger steps can be used in ray marching to render them. In addition, the density volumes of fogs and clouds can be easily generated using procedural materials, but game engines have not traditionally supported volume generation from particles. This means that current plug-ins are specific to rendering low-density mediums, namely clouds and fogs, and cannot be directly applied to render high-density dynamic particles.

Accordingly, embodiments of the present disclosure include a method for real-time volumetric rendering of dynamic translucent particles and an apparatus to reduce computational overheads of rendering dynamic snow particles while ensuring that the simulated snow appears realistic. While snow particles are used as an example, it is noted that aspects of the present disclosure may be applied to simulation of dynamic particles of other high-density translucent materials, such as ash, dust, etc. A graphics processing pipeline may begin with converting dynamic particles into a volume texture and then using ray marching to compute the interaction between light and medium. The subject matter described herein can be implemented to realize one or more benefits or advantages. For instance, the embodiment allows for realistic volume rendering of dynamic snow particles in real-time applications such as video games. In addition, the embodiment can produce more realistic shading and depict better volume of the high-density natural particles compared to related techniques.

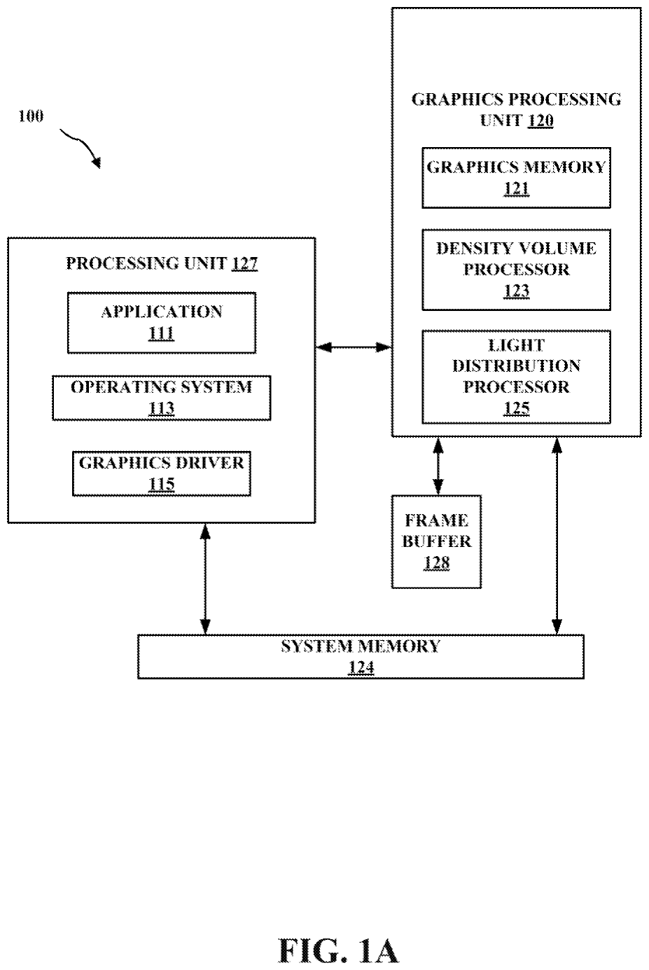

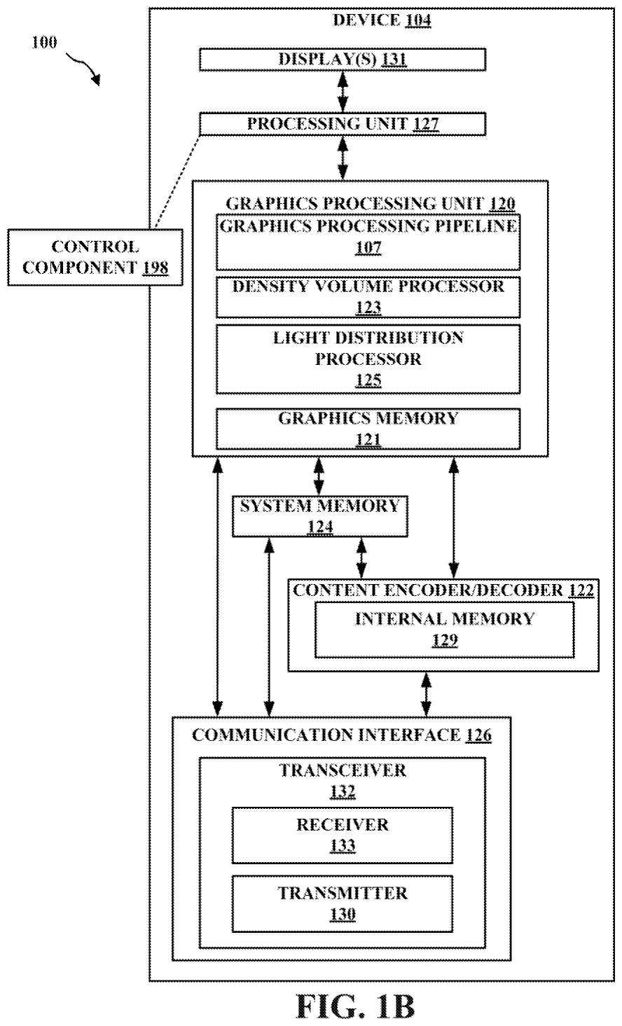

FIG. 1A is a block diagram that illustrates an example content generation system 100 configured to implement one or more techniques of this disclosure. The content generation system 100 includes a processing unit 127, a GPU 120, and a system memory 124 configured to render a 3D scene according to an exemplary aspect. Processing unit 127 may execute software application 111, operating system (OS) 113, and graphics driver 115. Moreover, system memory 124 may include indirect buffers that store the command streams for rendering primitives as well as secondary commands that are to be executed by GPU 120. GPU 120 may include graphics memory (GMEM) 121 that may be “on-chip” with GPU 120 that is coupled to a density volume processor 123 and a light distribution processor 125. As described in more detail with respect to FIG. 1B, the components of content generation system 100 may be part of a device, including, but are not limited to, video devices, media players, set-top boxes, wireless handsets such as mobile telephones and so-called smartphones, personal digital assistants (PDAs), desktop computers, laptop computers, gaming consoles, video conferencing units, tablet computing devices, and the like.

Processing unit 127 may include one or more of the central processing unit (CPU). GPU 120 may include a processing unit configured to perform graphics related functions such as generate and output graphics data for presentation on a display, as well as perform non-graphics related functions that exploit the massive processing parallelism provided by GPU 120. Because GPU 120 may provide general-purpose processing capabilities in addition to graphics processing capabilities, GPU 120 may be referred to as a general-purpose GPU (GP-GPU). Examples of processing unit 127 and GPU 120 include, but are not limited to, a digital signal processor (DSP), a general-purpose microprocessor, application specific integrated circuit (ASIC), field programmable logic array (FPGA), or other equivalent integrated or discrete logic circuitry. In some examples, GPU 120 may be a microprocessor designed for specific usage such as providing massive parallel processing for processing graphics, as well as for executing non-graphics related applications. Furthermore, although processing unit 127 and GPU 120 are illustrated as separate components, aspects of this disclosure are not so limited and can be, for example, implemented in a common integrated circuit (IC).

Software application 111 that executes on processing unit 127 may include one or more graphics rendering instructions that instruct processing unit 127 to cause the rendering of graphics data to a display (not shown in FIG. 1A). In some examples, the graphics rendering instructions may include software instructions that may conform to a graphics application programming interface (API). In order to process the graphics rendering instructions, processing unit 127 may issue one or more graphics rendering commands to GPU 120 (e.g., through graphics driver 115) to cause GPU 120 to perform some or all of the rendering of the graphics data. In some examples, the graphics data to be rendered may include a list of graphics primitives, e.g., points, lines, triangles, quadrilaterals, triangle strips, etc.

GPU 120 may be configured to perform graphics operations to render one or more graphics primitives to a display. Accordingly, when one of the software applications executing on processing unit 127 requires graphics processing, processing unit 127 may provide graphics commands and graphics data to GPU 120 for rendering to the display. The graphics data may include, e.g., drawing commands, state information, primitive information, texture information, etc. GPU 120 may, in some instances, be built with a highly parallel structure that provides more efficient processing of complex graphic-related operations than processing unit 127. For example, GPU 120 may include a plurality of processing elements that are configured to operate on multiple vertices or pixels in a parallel manner.

GPU 120 may be directly coupled to GMEM 121. In other words, GPU 120 may process data locally using a local storage, instead of off-chip memory. This allows GPU 120 to operate in a more efficient manner by eliminating the need of GPU 120 to read and write data via, e.g., a shared bus, which may experience heavy bus traffic. GMEM 121 may include one or more volatile or non-volatile memories or storage devices, e.g., random access memory (RAM), static RAM (SRAM), dynamic RAM (DRAM), and one or more registers.

The GMEM 121 may also be directly coupled to at least a density volume processor 123 and a second processor (e.g., a light distribution processor 125). The density volume processor 123 may be configured to convert particle data representing each of the dynamic particles into a density volume representing a density distribution of respective dynamic particles distributed in 3D space. The light distribution processor 125 may be configured to precompute a light distribution within the density volume representing a light value for each grid point within the density volume using ray marching from a light source. In some aspects, the grid points within the density volume may correspond to fixed reference positions. In some aspects, the processors that perform the above-described functions may be general processors (e.g., CPU).

The density volume processor 123 may be a CPU, a GPU, a general-purpose GPU (GPGPU), or any other processing unit that may be configured to perform graphics processing. In some examples, the density volume processor 123 may be integrated into a motherboard of the device 104. In some examples, the density volume processor 123 may be present on a graphics card that is installed in a port in a motherboard of the device 104 or may be otherwise incorporated within a peripheral device configured to interoperate with the device 104. The density volume processor 123 may include one or more processors, such as one or more microprocessors, GPUs, application specific integrated circuits (ASICs), field programmable gate arrays (FPGAs), arithmetic logic units (ALUs), digital signal processors (DSPs), discrete logic, software, hardware, firmware, other equivalent integrated or discrete logic circuitry, or any combinations thereof. If the techniques are implemented partially in software, the density volume processor 123 may store instructions for the software in a suitable, non-transitory computer-readable storage medium, e.g., internal memory 121, and may execute the instructions in hardware using one or more processors to perform the techniques of this disclosure. Any of the foregoing, including hardware, software, a combination of hardware and software, etc., may be considered to be one or more processors.

The light distribution processor 125 may be a CPU, a GPU, a general-purpose GPU, or any other processing unit that may be configured to perform graphics processing. In some examples, light distribution processor 125 may be integrated into a motherboard of the device 104. In some examples, the light distribution processor 125 may be present on a graphics card that is installed in a port in a motherboard of the device 104 or may be otherwise incorporated within a peripheral device configured to interoperate with the device 104. The light distribution processor 125 may include one or more processors, such as one or more microprocessors, GPUs, ASICs, FPGAs, ALUs, DSPs, discrete logic, software, hardware, firmware, other equivalent integrated or discrete logic circuitry, or any combinations thereof. If the techniques are implemented partially in software, the light distribution processor 125 may store instructions for the software in a suitable, non-transitory computer-readable storage medium, e.g., internal memory 121, and may execute the instructions in hardware using one or more processors to perform the techniques of this disclosure. Any of the foregoing, including hardware, software, a combination of hardware and software, etc., may be considered to be one or more processors.

Processing unit 127 and/or GPU 120 may store rendered image data in a frame buffer 128, which may be an independent memory or may be allocated within system memory 124. A display processor may retrieve the rendered image data from frame buffer 128 and display the rendered image data on a display.

System memory 124 may be a memory in the device and may reside external to processing unit 127 and GPU 120, i.e., off-chip with respect to processing unit 127, and off-chip with respect to GPU 120. System memory 124 may store applications that are executed by processing unit 127 and GPU 120. Furthermore, system memory 124 may store data upon which the executed applications operate, as well as the data that result from the application.

System memory 124 may store program modules, instructions, or both that are accessible for execution by processing unit 127, data for use by the programs executing on processing unit 127, or two or more of these. For example, system memory 124 may store a window manager application that is used by processing unit 127 to present a graphical user interface (GUI) on a display. In addition, system memory 124 may store user applications and application surface data associated with the applications. As explained in detail below, system memory 124 may act as a device memory for GPU 120 and may store data to be operated on by GPU 120 as well as data resulting from operations performed by GPU 120. For example, system memory 124 may store any combination of texture buffers, depth buffers, stencil buffers, vertex buffers, frame buffers, or the like.

Examples of system memory 124 include, but are not limited to, a random-access memory (RAM), a read only memory (ROM), or an electrically erasable programmable read-only memory (EEPROM), or any other medium that can be used to carry or store desired program code in the form of instructions or data structures and that can be accessed by a computer or a processor. As one example, system memory 124 may be removed from the device, and moved to another device. As another example, a storage device, substantially similar to system memory 124, may be inserted into the device.

FIG. 1B is a more detailed block diagram that illustrates an example content generation system 100 configured to implement one or more techniques of this disclosure. It is noted that the content generation system 100 shown in FIG. 1B may corresponds to the content generation system of FIG. 1A. In this regard, the content generation system 100 of FIG. 1B includes a processing unit 127, a GPU 120, and a system memory 124.

As further shown, the content generation system 100 includes a device 104 that may include one or more components configured to perform one or more techniques of this disclosure. In the example shown, the device 104 may include a GPU 120, a content encoder/decoder 122, and system memory 124. In some aspects, the device 104 can include a number of additional components, e.g., a communication interface 126, a transceiver 132, a receiver 133, and a transmitter 130, and one or more displays 131. Reference to the display 131 may refer to the one or more displays 131. For example, the display 131 may include a single display or multiple displays. The display 131 may include a first display and a second display. In further examples, the results of the graphics processing may not be displayed on the device, e.g., the displays 131 may not receive any frames for presentment thereon. Instead, the frames or graphics processing results may be transferred to another device. In some aspects, this can be referred to as hybrid-rendering.

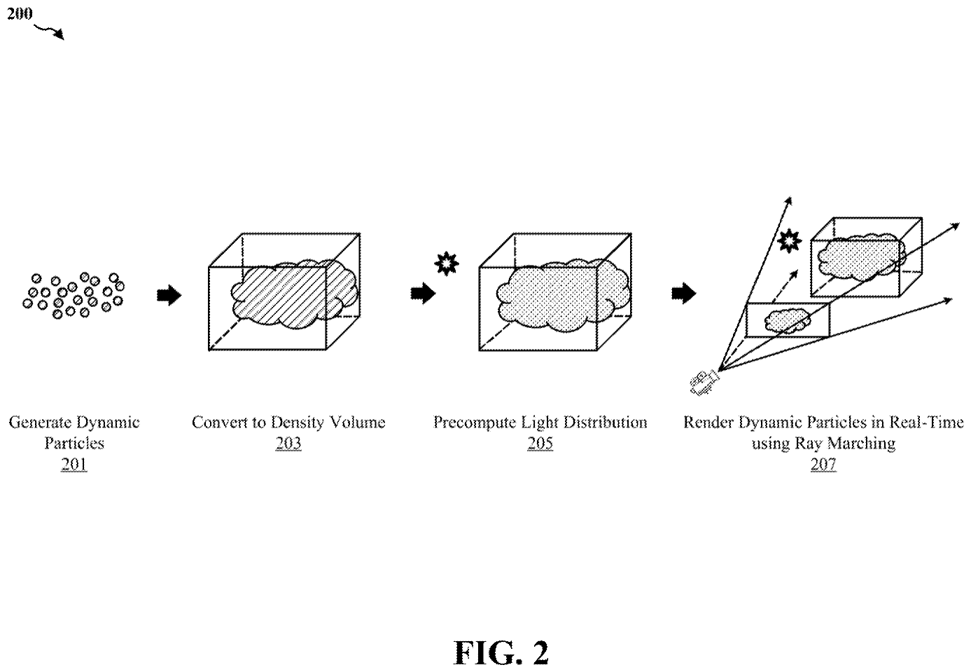

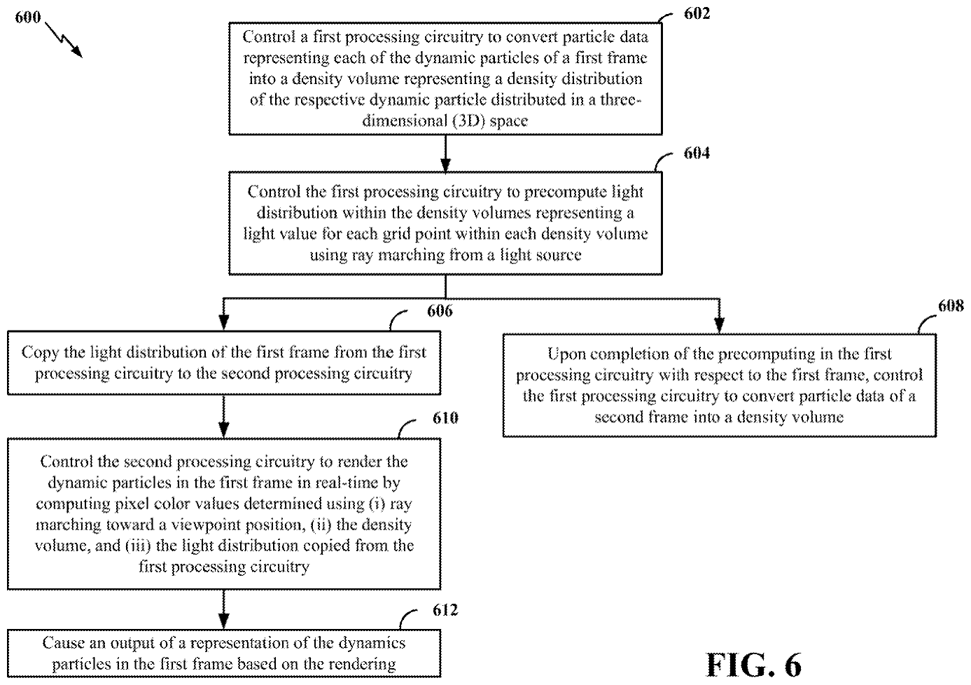

The GPU 120 includes GMEM 121. The GPU 120 may be configured to perform graphics processing, such as in a graphics processing pipeline 107. The graphics processing pipeline 107 may include at least generating dynamic particles, converting the dynamic particles to a density volume, precomputing light volume, and then rendering volume using ray marching, as will be described in more detail in FIGS. 2 and 6. The GPU 120 may be configured to perform these steps in the graphics processing pipeline 107 using at least the GMEM 121, a density volume processor 123 coupled to the GMEM 121, and a second processor (e.g., light distribution processor 125) coupled to the GMEM 121. The content encoder/decoder 122 may include an internal memory 129. In some examples, the device 104 may include a display processor, such as the processing unit 127, to perform one or more display processing techniques on one or more frames generated by the GPU 120 before presentment by the one or more displays 131 as described above. The processing unit 127 may be configured to perform display processing. The one or more displays 131 may be configured to display or otherwise present frames processed by the processing unit 127. In some examples, the one or more displays 131 may include one or more of: a liquid crystal display (LCD), a plasma display, an organic light emitting diode (OLED) display, a projection display device, an augmented reality display device, a virtual reality display device, a head-mounted display, or any other type of display device.

Memory external to the GPU 120 and the content encoder/decoder 122, such as system memory 124 as described above, may be accessible to the GPU 120 and the content encoder/decoder 122. For example, the GPU 120 and the content encoder/decoder 122 may be configured to read from and/or write to external memory, such as the system memory 124. The GPU 120 and the content encoder/decoder 122 may be communicatively coupled to the system memory 124 over a bus. In some examples, the GPU 120 and the content encoder/decoder 122 may be communicatively coupled to each other over the bus or a different connection.

The content encoder/decoder 122 may be configured to receive graphical content from any source, such as the system memory 124 and/or the communication interface 126. The system memory 124 may be configured to store received encoded or decoded graphical content. The content encoder/decoder 122 may be configured to receive encoded or decoded graphical content, e.g., from the system memory 124 and/or the communication interface 126, in the form of encoded pixel data. The content encoder/decoder 122 may be configured to encode or decode any graphical content.

The GMEM 121 or the system memory 124 may be a non-transitory computer-readable storage medium according to some examples. The term “non-transitory” may indicate that the storage medium is not embodied in a carrier wave or a propagated signal. However, the term “non-transitory” should not be interpreted to mean that GMEM 121 or the system memory 124 is non-movable or that its contents are static. As one example, the system memory 124 may be removed from the device 104 and moved to another device. As another example, the system memory 124 may not be removable from the device 104.

The GPU (or processing circuitry) may be configured to perform graphics processing according to the exemplary techniques as described herein. In some examples, the GPU 120 may be integrated into a motherboard of the device 104. In some examples, the GPU 120 may be present on a graphics card that is installed in a port in a motherboard of the device 104, or may be otherwise incorporated within a peripheral device configured to interoperate with the device 104. The GPU 120 may include one or more processors, such as one or more microprocessors, GPUs, ASICs, FPGAs, ALUs, DSPs, discrete logic, software, hardware, firmware, other equivalent integrated or discrete logic circuitry, or any combinations thereof. If the techniques are implemented partially in software, the GPU 120 may store instructions for the software in a suitable, non-transitory computer-readable storage medium and may execute the instructions in hardware using one or more processors to perform the techniques of this disclosure. Any of the foregoing, including hardware, software, a combination of hardware and software, etc., may be considered to be one or more processors.

The content encoder/decoder 122 may be any processing unit configured to perform content encoding/decoding. In some examples, the content encoder/decoder 122 may be integrated into a motherboard of the device 104. The content encoder/decoder 122 may include one or more processors, such as one or more microprocessors, ASICs, FPGAs, ALUs, DSPs, video processors, discrete logic, software, hardware, firmware, other equivalent integrated or discrete logic circuitry, or any combinations thereof. If the techniques are implemented partially in software, the content encoder/decoder 122 may store instructions for the software in a suitable, non-transitory computer-readable storage medium, e.g., internal memory 129, and may execute the instructions in hardware using one or more processors to perform the techniques of this disclosure. Any of the foregoing, including hardware, software, a combination of hardware and software, etc., may be considered to be one or more processors.

In some aspects, the content generation system 100 can include a communication interface 126. The communication interface 126 may include a receiver 133 and a transmitter 130. The receiver 133 may be configured to perform any receiving function described herein with respect to the device 104. Additionally, the receiver 133 may be configured to receive information, e.g., eye or head position information, rendering commands, or location information, from another device. The transmitter 130 may be configured to perform any transmitting function described herein with respect to the device 104. For example, the transmitter 130 may be configured to transmit information to another device, which may include a request for content. The receiver 133 and the transmitter 130 may be combined into a transceiver 132. In such examples, the transceiver 132 may be configured to perform any receiving function and/or transmitting function described herein with respect to the device 104.

Referring again to FIG. 1B, in certain aspects, the processing unit 127 may include a control component 198 that is configured to control the processor (comprising a CPU or GPU) or general-purpose processor to perform real-time volumetric rendering of high-density particles. Moreover, the control component 198 can be configured to convert particle data representing each of the dynamic particles into a density volume representing a density distribution of dynamic particles distributed in a three-dimensional (3D) space, precompute a light distribution within the density volume representing a light value for each grid point within the density volume using ray marching from a light source, render the dynamic particles in real-time by computing pixel color values determined using (i) ray marching toward a viewpoint position, (ii) the density volume, and (iii) the light distribution, and output a representation of the dynamic particles based on the rendering.

As described herein, a device, such as the device 104, may refer to any device, apparatus, or system configured to perform one or more techniques described herein. For example, a device may be a server, a base station, user equipment, a client device, a station, an access point, a computer, e.g., a personal computer, a desktop computer, a laptop computer, a tablet computer, a computer workstation, or a mainframe computer, an end product, an apparatus, a phone, a smart phone, a server, a video game platform or console, a handheld device, e.g., a portable video game device or a personal digital assistant (PDA), a wearable computing device, e.g., a smart watch, an augmented reality device, or a virtual reality device, a non-wearable device, a display or display device, a television, a television set-top box, an intermediate network device, a digital media player, a video streaming device, a content streaming device, an in-car computer, any mobile device, any device configured to generate graphical content, or any device configured to perform one or more techniques described herein. Processes herein may be described as performed by a particular component, e.g., a GPU, but, in further embodiments, can be performed using other components, e.g., a CPU, consistent with disclosed embodiments.

FIG. 2 illustrates an example diagram for a graphics processing in accordance with one or more techniques of this disclosure. Specifically, FIG. 2 shows an example diagram of a graphics processing pipeline 200 for real-time volumetric rendering of dynamic particles. As shown in FIG. 2, the graphics processing pipeline 200 includes a dynamic particle generation stage 201, a conversion stage 203, a precomputation stage 205, and a rendering stage 207.

First, the graphics processing pipeline 200 begins with generating dynamic snow particles from a physically-based simulation 201. A physically-based modeling and simulation system is configured to map natural phenomena to a computer simulation program. Physical simulation is used in movies and video games to animate a variety of phenomena such as explosions, car crashes, water, cloth, snow, and so on.

Next, the graphics processing pipeline 200 includes converting the dynamic particles into density volume 203. The density volume represents a density distribution of the respective dynamic particles distributed in a 3D space. For instance, simulated translucent materials (e.g., snow, ash, dust, etc.) may be represented as particles having a radius and position in 3D space. Given the particle data, the particles may then be converted to a density value (or volume texture) that represents the density of the material in a 3D grid. For each particle, a density contribution to each grid point within the particle's radius may be computed and accumulated to obtain a final density distribution in space.

The graphics processing pipeline 200 then includes precomputing light distribution within the density volume 205. The light distribution represents a light value for each grid point within the density volume using ray marching from a light source. The grid points within the density volume may correspond to fixed reference positions. To accelerate rendering, the light distribution may be precomputed within the volume and used later during rendering. In the context of graphics rendering within a video game, the light distribution may be precomputed because the position of the light source is known ahead of time. If the density volume or light source changes, the light distribution may be recomputed.

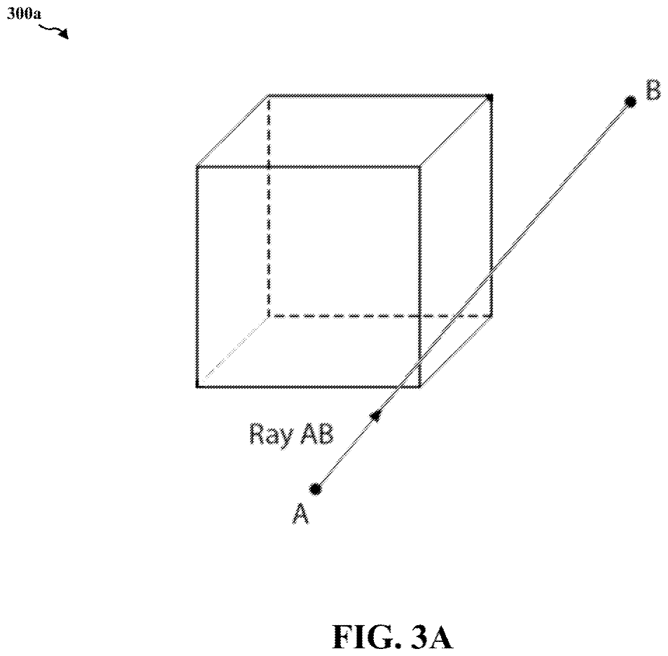

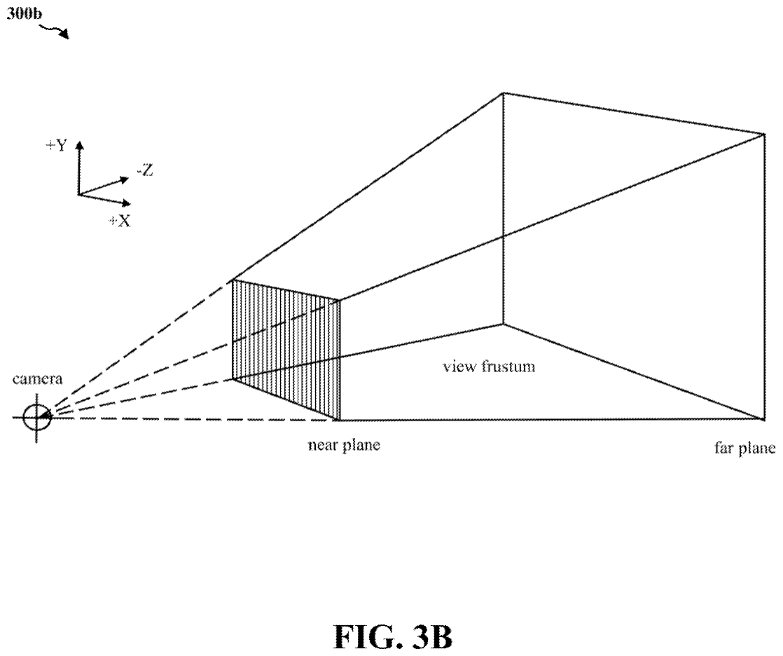

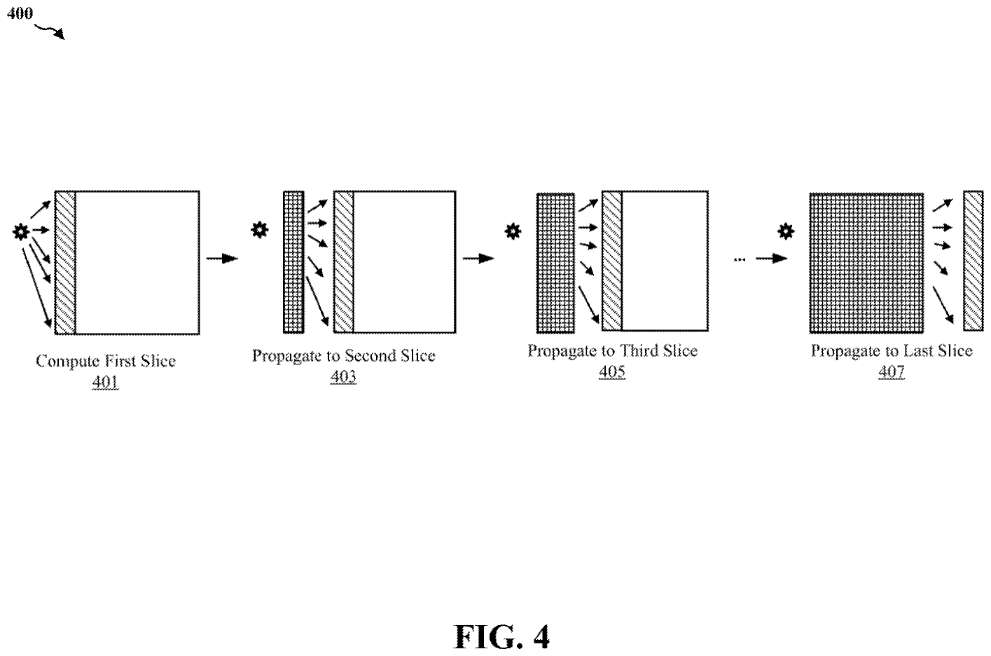

In some aspects, the light distribution may be considered as another volume texture. For each grid point, the light value is computed using ray marching. Different methods of representing the density volume and the light distribution will be described with respect to FIGS. 3A-3B below. In addition, several different methods of pre-computing the lighting distribution will be described in further detail below with reference to FIG. 4.

As described herein, the graphics processing pipeline 200 may include precomputing the lighting distribution in a few different ways. In a first aspect, the most straight-forward way is to precompute the lighting distribution by creating a volume texture with a same resolution as a density volume and using ray marching to compute the light at each voxel in parallel. In a second aspect, the resolution of the light volume may be lower than the resolution of the density volume and then interpolated to obtain the light value at a queried location. In a third aspect, instead of computing the light at each voxel in parallel, we can compute the light volume using a slice-by-slice technique, as will be shown in FIG. 4 below.

The graphics processing pipeline 200 then includes rendering dynamic particles in real-time using ray marching 207. Rendering is performed by computing pixel color values determined using ray marching toward a viewpoint position, the density volume, and the precomputed light distribution. As described above, ray marching is a computer graphics technique that shoots a ray which goes through a volume of medium. Samples are then taken at fixed intervals along the way to calculate the interaction between light and the medium and calculations are accumulated along the ray to obtain the display parameters of the volume. Specifically, each pixel may shoot a ray in a direction of the camera and samples may be taken on the ray sections that intersect with the density volume to determine display parameters of that pixel. Lighting may then be retrieved from the precomputed light volume at each sample. A scattered radiance value is then computed and accumulated to generate a final pixel color value for display.

The advantages of this graphics processing pipeline 200 include applying at least real-time volumetric rendering to simulate high-density translucent natural materials such as snow, ash, or dust. Related real-time volume rendering techniques for low-density mediums such as volumetric clouds and volumetric fogs have been used in game engines, but were not able to be directly applied to high-density natural materials because the high-density natural materials were not able to be rendered efficiently with large ray marching steps.

Until recently, accurate physically-based algorithms for realistically simulating and rending high-density natural materials have been difficult due to being too prohibitively computationally expensive to be applied to real-time applications. It is just now starting to become feasible to physically simulate and render these effects in real-time as a result of the rapid development of computing power in GPUs. In addition, as compared to related snow rendering techniques such as using sprites or polygon meshes with subsurface scattering materials, the graphics processing pipeline 200 creates more accurate shadows and realistic granular results of volume of high-density materials.

FIG. 3A illustrates an example diagram of representing density and lighting distribution as an axis-aligned bounding box in accordance with one or more techniques of this disclosure. Example 300a represents the density and lighting distribution in 3D using a 3D box that aligns with a Cartesian axis (e.g., axis-aligned bounding box). This method is a quick and straightforward way of representing the density and light, but has some drawbacks because objects in the grid near the camera may appear blurred because the grid points near the camera may appear too far apart on the screen due to perspective projection. This may result in blurred visual results for particles close to the camera.

FIG. 3B illustrates an example diagram of representing density and lighting distribution as a froxel volume in accordance with one or more techniques of this disclosure. Example 300b represents the density and lighting distribution in 3D using a “froxel volume.” Froxel is a combination of the words “Frustum” and “voxel,” which means that the voxel grids are arranged in a frustum shape that aligns with the camera frustum and moves together with the camera. A frustum shape is a portion of a solid like a cone or a clipped pyramid. The frustrum is usually used in game engines to render objects that are located inside the camera frustum. Camera frustrum represents the zone of vision of a camera. The benefit of froxel is that the grid is denser in regions near the camera, which creates sharper visual results than the 3D box method (e.g., as shown in FIG. 3A) with the same number of voxels.

Results from a comparison between representing the density and lighting distribution in 3D using a 3D box and representing the density and lighting distribution in 3D using a Froxel to render a scene with snow are shown below.

TABLE 1
Performance Comparison between Froxel and AABB

| | 3D Box | Froxel |
|---|---|---|
| Time per Frame (ms) | 39.41 | 29.78 |
| Frame Rate (FPS) | 25.37 | 33.58 |

As compared to the 3D box method explained in FIG. 3A, using a froxel volume reduces the number of voxels needed to reach the same visual quality as compared with the 3D box method. Therefore, the froxel volume method reduces computation cost and increases the frame rate.

FIG. 4 illustrates an example of a slice-by-slice light precomputation in accordance with one or more techniques of this disclosure. The slice-by-slice light precomputation may be an effective method of computing light distribution. The general idea of the slice-by-slice technique is that for each slice, the light computation depends on the result of the previous slice.

As shown in example 400, the first step involves determining a light precomputation for an initial slice from a plurality of volume slices 401, propagating the results of the light precomputation from the initial slice when determining a light precomputation for a second volume slice 403, propagating the results of the light precomputation from the second slice when determining a light precomputation for a third volume slice 405, and so forth until propagating the results of the light precomputation from the second to last slice when determining a light precomputation for the last volume slice 407. In this way, the slice-by-slice light precomputation avoids redundant ray shooting and provides faster computation when compared to computing all voxels in parallel.

Based on a comparison between no light precomputation, per voxel precomputation, and slice-by-slice precomputation, the slice-by-slice precomputation can greatly outperform both the no light precomputation method and the per voxel precomputation. Exemplary results from the comparison between the three precomputation methods are shown below:

TABLE 2
Computation Cost of Different Ways to Handle Light Computation

| | No Light | Per Voxel | Slice-by-slice |
|---|---|---|---|
| | Precomputation | Precomputation | Precomputation |
| Light Precomputation | 0 | 205.55 | 29.70 |
| Time (ms) | | | |
| Total Render | 149.49 | 208.92 | 33.07 |
| Time (ms) | | | |

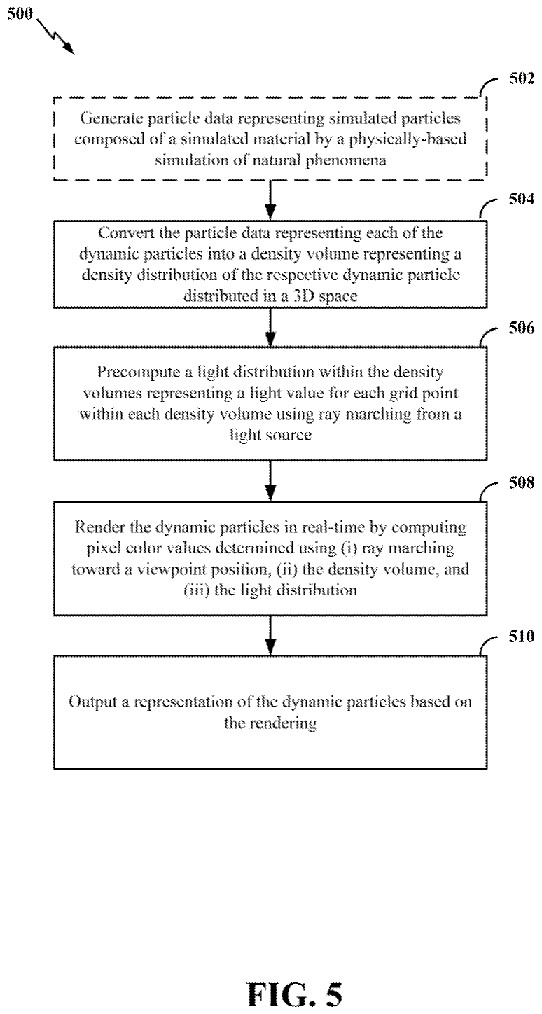

FIG. 5 illustrates a flowchart of various example methods for graphics processing in accordance with one or more techniques of this disclosure. The method 500 may be performed by an apparatus, such as control component 198, as described above. In some implementations, the method 500 is performed by processing logic, including hardware, firmware, software, or a combination thereof. In some implementations, the method 500 is performed by a processor executing code stored in a non-transitory computer-readable medium (e.g., a memory). The method 500 includes volumetric rendering of dynamic particles in real-time applications.

At block 502, the method 500 includes generating the particle data representing simulated particles composed of a simulated material by a physically-based simulation for simulating natural phenomena. The generated particles include movement of the simulated particles in the 3D space. In some aspects, the simulated material is snow. In some aspects, the simulated material is ash. In some aspects, the simulated material is dust. In some aspects, the simulated material has translucent properties or is a translucent material. For example, in the context of FIG. 2, the graphics processing pipeline 200 includes generating dynamic particles using a physically-based simulation for simulating natural phenomena 201.

At block 504, the method 500 includes converting particle data representing each of the respective dynamic particles into a density volume representing a density distribution of the respective dynamic particles distributed in a three-dimensional (3D) space. In some aspects, the conversion includes: determining, based on the particle data, a density value contribution for each grid point within a particle radius, and summing the density value contributions to obtain the density distribution of the dynamic particles distributed in the 3D space. For example, in the context of FIG. 2, graphics processing pipeline 200 includes converting the particle data into density volume 203.

In some aspects, the density volume and the light distribution are represented in a 3D box that aligns with a Cartesian coordinate axis. For example, in the context of FIG. 3A, example 300a represents the density volume and the light distribution using a 3D axis-aligned bounding box.

In some aspects, the density volume and the light distribution are represented using a froxel volume aligned to the camera position. For example, in the context of FIG. 3B, example 300b represents the density volume and the light distribution using a froxel.

At block 506, the method 500 includes precomputing a light distribution within the density volume representing a light value for each grid point within the density volume using ray marching from a light source. In some aspects, precomputing the light distribution includes generating the light distribution with a same resolution as a resolution of the density distribution of the dynamic particles. A light value at each voxel of a respective grid point within the density volume is determined in parallel using the ray marching. For example, in the context of FIG. 2, graphics processing pipeline 200 includes precomputing light distribution 205.

In some aspects, the precomputation includes generating the light distribution with a resolution lower than a resolution of the density distribution of the dynamic particles, and interpolating the generated light distribution. This aspect is based on the idea that because the light distribution is typically smooth, the light volume may have a lower resolution than the density volume without significantly affecting the visual quality.

In some aspects, the precomputation includes generating a plurality of volume slices of the density volume, determining a light distribution result for an initial volume slice from the plurality of volume slices, and for each additional volume slice after the initial volume slice, determining a light distribution result of the respective additional volume slice by performing the ray marching based on a light distribution result from a previous volume slice. In addition, using the light volume with lower resolution also greatly reduces the computation cost and increases the frame rate. For example, in the context of FIG. 4, example 400 describes generating light distribution using a slice-by-slice technique.

At block 508, the method 500 includes rendering the dynamic particles in real-time by computing pixel color values determined using ray marching toward a viewpoint position, the density volume, and the light distribution. In some aspects, the pixel color values are computed by generating a ray for each pixel from the camera position, sampling the generated rays at sections that intersect with the density volume, retrieving a light value from the light distribution at each sample, and computing a scattered radiance value at each sample based on the retrieved light values and computing the pixel color values based on the scattered radiance values. For example, in the context of FIG. 2, graphics processing pipeline 200 includes rendering the dynamic particles in real-time using ray marching 207.

At block 510, the method 500 includes outputting a representation of the dynamic particles based on the rendering.

FIG. 6 shows a flowchart illustrating an example method 600 for graphic processing utilizing dual processing circuitry, e.g., GPUs, in accordance with one or more techniques of this disclosure. The method 600 may be performed by an apparatus, such as control component 198, as described above. In some implementations, the method 600 is performed by processing logic, including hardware, firmware, software, or a combination thereof. In some implementations, the method 600 is performed by a processor executing code stored in a non-transitory computer-readable medium (e.g., a memory). The method 600 describes volumetric rendering of dynamic particles using dual processing circuitry in real-time applications.

In some aspects, the method 600 includes generating the particle data representing simulated particles composed of a simulated material by a physically-based simulation of natural phenomena. The generated particle data includes movement of the simulated particles in the 3D space. In some aspects, the simulated material is snow. In some aspects, the simulated material is ash. In some aspects, the simulated material is dust. In some aspects, the simulated material has translucent properties or is a translucent material. For example, in the context of FIG. 2, the graphics processing pipeline 200 includes generating dynamic particles of the simulated material by a physically-based simulation of natural phenomena 201.

At block 602, the method 600 includes controlling the first processing circuitry to convert particle data representing each of the dynamic particles of a first frame into a density volume representing a density distribution of the respective dynamic particles distributed in a three-dimensional (3D) space. For example, in the context of FIG. 2, the graphics processing pipeline 200 includes converting the particle data into density volume 203.

At block 604, the method 600 includes controlling the first processing circuitry to precompute light distribution within the density volume representing a light value for each grid point within the density volume using ray marching from a light source. The grid points within the density volume correspond to fixed reference positions. For example, in the context of FIG. 2, the graphics processing pipeline 200 includes precomputing light distribution 205.

After block 604, blocks 606 and 608 are performed in parallel.

At block 606, the method 600 includes copying the light distribution of the first frame from the first processing circuitry to the second processing circuitry. In some aspects, copying the light distribution of the first frame from the first processing circuitry to the second processing circuitry is performed in parallel to the first processing circuitry initiating preprocessing of the second frame and before the second processing circuitry performs volumetric rendering of the first frame in real-time. In some aspects, block 606 includes copying both the light distribution and the density volume of the first frame from the first processing circuitry to the second processing circuitry. In other aspects, block 606 includes copying the light distribution of the first frame to the second processing circuitry and generating the density volume of the first frame in the second processing circuitry, so that the density volume does not have to be copied from the first processing circuitry.

At block 608, the method 600 includes, upon completion of the precomputing in the first processing circuitry with respect to the first frame, controlling the first processing circuitry to convert particle data of a second frame into a density volume. For example, in the context of FIG. 2, the graphics processing pipeline 200 includes converting the particle data into density volume 203. In other words, block 608 serves as the beginning of a new process 600 where the second frame is now the first frame.

At block 610, the method 600 includes controlling the second processing circuitry to render the dynamic particles in the first frame in real-time by computing pixel color values determined using ray marching toward a viewpoint position, the density volume, and the light distribution copied from the first processing circuitry. For example, in the context of FIG. 2, the graphics processing pipeline 200 includes rendering the dynamic particles in real-time using ray marching 207.

At block 612, the method 600 includes causing an output of a representation of the dynamic particles in the first frame based on the rendering.

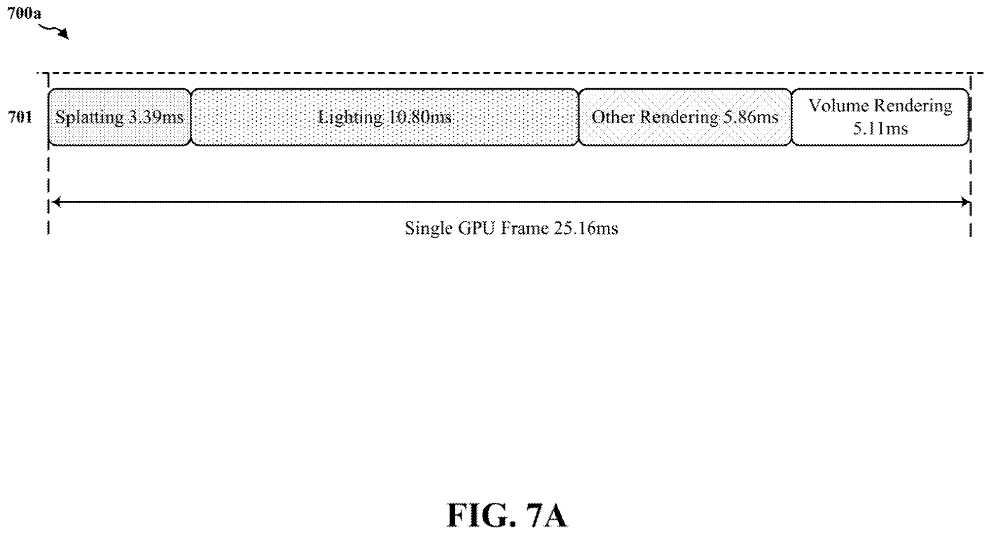

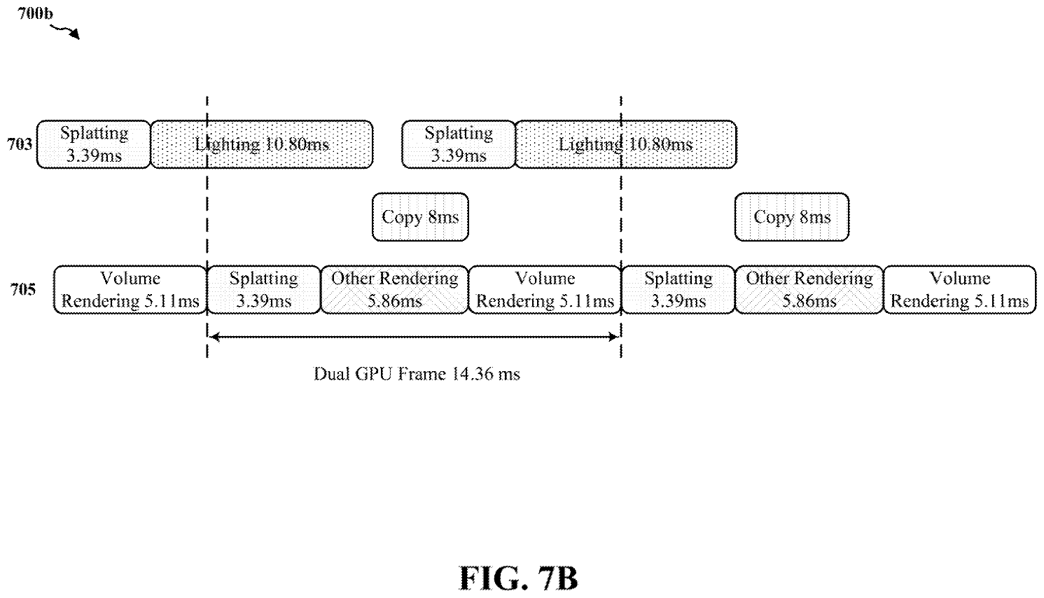

Specific interactions between the steps performed by a first processing circuitry and a second processing circuitry in performing real-time volumetric rendering of dynamic particles will be described below in more detail in FIG. 7B.

FIG. 7A illustrates an example diagram for a graphics processing pipeline using a single processing circuitry, e.g., a GPU, according to one or more techniques of this disclosure. Example 700a shows performing a real-time volumetric rendering of dynamic particles using a single GPU 701. Here, the splatting refers to the step of converting particle data into a density volume representing a density distribution of dynamic particles distributed in 3D space. The lighting refers to the step of precomputing a light distribution within the density volume representing a light value for each grid point within the density volume. Volume rendering refers to rendering the dynamic particles in real-time by computing pixel color values determined using ray marching with respect to a camera position, the density volume, and the light distribution and other rendering refers to other rendering processes such as object rendering with materials other than volumetric materials, shading, ray tracing, ray casting, refraction, texture mapping, or the like. Here, the total time to render a single GPU frame may take a total of 25.16 milliseconds.

FIG. 7B illustrates an example diagram for a graphics processing pipeline using multiple processing circuitries according to one or more techniques of this disclosure.

To further accelerate computation, multiple processing circuitries (e.g., GPUs) may be used in the rendering process. Example 700b shows using dual GPUs 703 and 705 to perform real-time volumetric rendering of dynamic particles. In example 700b, the dotted vertical lines align with the second GPU 705 to show the total time to render a single GPU frame by the second GPU. As compared to using a single GPU as shown in example 700a, example 700b shows that using dual GPUs to perform real-time volumetric rendering of dynamic particles will cut the time to render a single GPU frame significantly.

Example 700b shows that the first GPU 703 converts particle data of a first frame into a density volume representing a density of dynamic particles distributed in a three-dimensional (3D) space and precomputes light distribution within the density volume representing a light value for each grid point within the density volume in the first frame using ray marching with respect to a light source. Next, the light distribution of the first frame is copied from the first GPU to the second GPU. The copying process is performed in parallel to the other steps performed by the first GPU and second GPU such that by the time the second GPU performs preliminary rendering of the first frame, the first GPU has already moved onto the second frame. Additionally, the second GPU begins converting particle data of the first frame into a density volume (shown as “Splatting” in FIG. 7B) while the first GPU is in the process of precomputing the light distribution for the first frame. Accordingly, once the light distribution of the first frame is copied to the second GPU, the second GPU is prepared to perform the rendering based on the light distribution and the density volume of the first frame. In this way, the different steps may be performed simultaneously on different GPUs and the frame rate is increased by 30%.

Exemplary results from the performance between performing real-time volumetric rendering of dynamic particles using a single GPU vs. using dual GPUs for rendering a scene involving snow are shown below.

TABLE 3
Performance Comparison between Single and Dual GPU

| | Single GPU | Dual GPU |
|---|---|---|
| Time per Frame (ms) | 25.16 | 19.03 |
| Frame Rate (FPS) | 39.75 | 52.55 |

The subject matter described herein can be implemented to realize one or more benefits or advantages. For instance, the techniques disclosed herein enable a method for real-time volumetric rendering of dynamic particles such as snow. As a result, realistic simulations of high-density natural materials may be volumetrically rendered in real-time applications such as video games. In addition, the techniques disclosed herein also create more realistic shadow and depict high-density volume more efficiently and with better visual qualities than related real-time techniques.

The subject matter described herein can be implemented to realize one or more benefits or advantages. For instance, the described graphics processing techniques can be used by a server, a client, a GPU, a CPU, or some other processor that can perform computer or graphics processing to implement the sharing techniques described herein. This can also be accomplished at a low cost compared to other computer or graphics processing techniques. Moreover, the computer or graphics processing techniques herein can improve or speed up data processing or execution. Further, the computer or graphics processing techniques herein can improve resource or data utilization and/or resource efficiency.

In accordance with this disclosure, the term “or” may be interrupted as “and/or” where context does not dictate otherwise. Additionally, while phrases such as “one or more” or “at least one” or the like may have been used for some features disclosed herein but not others, the features for which such language was not used may be interpreted to have such a meaning implied where context does not dictate otherwise.

In one or more examples, the functions described herein may be implemented in hardware, software, firmware, or any combination thereof. For example, although the term “processing unit” has been used throughout this disclosure, such processing unit may be implemented in hardware (e.g., by processing circuitry), software, firmware, or any combination thereof. If any function, processing unit, technique described herein, or other module is implemented in software, the function, processing unit, technique described herein, or other module may be stored on or transmitted over as one or more instructions or code on a computer-readable medium. Computer-readable media may include computer data storage media or communication media including any medium that facilitates transfer of a computer program from one place to another. In this manner, computer-readable media generally may correspond to (1) tangible computer-readable storage media, which is non-transitory or (2) a communication medium such as a signal or carrier wave. Data storage media may be any available media that can be accessed by one or more computers or one or more processors to retrieve instructions, code and/or data structures for implementation of the techniques described in this disclosure. By way of example, and not limitation, such computer-readable media can comprise RAM, ROM, EEPROM, CD-ROM or other optical disk storage, magnetic disk storage or other magnetic storage devices. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media. A computer program product may include a computer-readable medium.

The code may be executed by one or more processors, such as one or more digital signal processors (DSPs), general purpose microprocessors, application specific integrated circuits (ASICs), arithmetic logic units (ALUs), field programmable logic arrays (FPGAs), or other equivalent integrated or discrete logic circuitry. Accordingly, the term “processor,” as used herein may refer to any of the foregoing structure or any other structure suitable for implementation of the techniques described herein. Also, the techniques could be fully implemented in one or more circuits or logic elements.

The techniques of this disclosure may be implemented in a wide variety of devices or apparatuses, including a wireless handset, an integrated circuit (IC) or a set of ICs, e.g., a chip set. Various components, modules or units are described in this disclosure to emphasize functional aspects of devices configured to perform the disclosed techniques, but do not necessarily need realization by different hardware units. Rather, as described above, various units may be combined in any hardware unit or provided by a collection of inter-operative hardware units, including one or more processors as described above, in conjunction with suitable software and/or firmware.

What is claimed is:

1. A method for real-time volumetric rendering of dynamic particles, comprising:
converting particle data representing each of the dynamic particles into a density volume representing a density distribution of the respective dynamic particle distributed in a three-dimensional (3D) space,
precomputing a light distribution within the density volume representing a light value for each grid point within the density volume using ray marching from a light source, grid points within the density volume corresponding to fixed reference positions;
rendering the dynamic particles in real-time by computing pixel color values determined using (i) ray marching toward a viewpoint position, (ii) the density volume, and (iii) the light distribution; and
outputting a representation of the dynamic particles based on the rendering.

2. The method of claim 1, further comprising:
generating the particle data representing simulated particles composed of a simulated material by a physically-based simulation of natural phenomena, wherein the generated particle data includes movement of the simulated particles in the 3D space.

3. The method of claim 2, wherein the simulated material is snow.

4. The method of claim 2, wherein the simulated material is ash.

5. The method of claim 2, wherein the simulated material is dust.

6. The method of claim 2, wherein the simulated material is translucent.

7. The method of claim 1, wherein the converting comprises:
determining, based on the particle data, a density value contribution for each grid point within a particle radius, and
summing the density value contributions to obtain the density distribution of the dynamic particles distributed in the 3D space.

8. The method of claim 1, wherein the density volume and the light distribution are represented in a 3D box that aligns with a Cartesian coordinate axis.

9. The method of claim 1, wherein the density volume and the light distribution are represented using a froxel volume aligned to the viewpoint position.

10. The method of claim 1, wherein the precomputing the light distribution comprises:
generating the light distribution with a same resolution as a resolution of the density distribution of the dynamic particles, wherein the light value at each voxel of a respective grid point within the density volume is determined in parallel using the ray marching.

11. The method of claim 1, wherein the precomputing the light distribution comprises:
generating the light distribution with a resolution lower than a resolution of the density distribution of the dynamic particles; and
interpolating the generated light distribution.

12. The method of claim 1, wherein the precomputing the light distribution comprises:
generating a plurality of volume slices of the density volume,
determining a light distribution result for an initial volume slice from the plurality of volume slices, and
for each additional volume slice after the initial volume slice, determining a light distribution result of the respective additional volume slice by performing the ray marching based on a light distribution result from a previous volume slice.

13. The method of claim 1, wherein the pixel color values are computed by:
generating a ray for each pixel from the viewpoint position;
sampling the generated rays at sections that intersect with the density volume;
retrieving a light value from the light distribution at each sample; and
computing a scattered radiance value at each sample based on the retrieved light values and computing the pixel color values based on the scattered radiance values.

14. An apparatus for real-time volumetric rendering of dynamic particles, the apparatus comprising:
processing circuitry configured to
convert particle data representing each of the dynamic particles into a density volume representing a density distribution of the respective dynamic particle distributed in a three-dimensional (3D) space,
precompute a light distribution within the density volume representing a light value for each grid point within the density volume using ray marching from a light source, grid points within the density volume corresponding to fixed reference positions;
render the dynamic particles in real-time by computing pixel color values determined using (i) ray marching toward a viewpoint position, (ii) the density volume, and (iii) the light distribution, and
cause an output of a representation of the dynamic particles based on the rendering.

15. The apparatus of claim 14, wherein the processing circuitry is further configured to:
generate the particle data representing simulated particles composed of a simulated material by a physically-based simulation of natural phenomena, wherein the generated particle data includes movement of the simulated particles in the 3D space.

16. The apparatus of claim 15, wherein the simulated material is snow.

17. The apparatus of claim 14, wherein the density volume and the light distribution are represented in a 3D box that aligns with a Cartesian coordinate axis.

18. A system for real-time volumetric rendering of dynamic particles, comprising:
first processing circuitry,
second processing circuitry, and
control circuitry configured to:
control the first processing circuitry to convert particle data representing each of the dynamic particles of a first frame into a density volume representing a density distribution of the respective dynamic particle distributed in a three-dimensional (3D) space;
control the first processing circuitry to precompute light distribution within the density volume representing a light value for each grid point within the density volume using ray marching from a light source, grid points within the density volume corresponding to fixed reference positions;
copy the light distribution of the first frame from the first processing circuitry to the second processing circuitry,
upon completion of the precomputing in the first processing circuitry with respect to the first frame, control the first processing circuitry to convert particle data of a second frame into a density volume;
control the second processing circuitry to render the dynamic particles in the first frame in real-time by computing pixel color values determined using (i) ray marching toward a viewpoint position, (ii) the density volume, and (iii) the light distribution copied from the first processing circuitry; and
cause an output of a representation of the dynamic particles in the first frame based on the rendering.

19. The system of claim 18, wherein the copying of the light distribution of the first frame from the first processing circuitry to the second processing circuitry is performed in parallel to the first processing circuitry initiating preprocessing of the second frame and before the second processing circuitry performs volumetric rendering of the first frame in real-time.

20. The system of claim 18, wherein the system is further configured to:
generate the particle data representing simulated particles composed of a simulated material by a physically-based simulation of natural phenomena, wherein the generated particle data includes movement of the simulated particles in the 3D space.
